(19) United States
(12) Patent Application Publication
(10) Pub. No.: US 2021/0142133 A1
(43) Pub. Date: May 13, 2021

(54) REFLECTION AND INVERSION INVARIANT CODES

(71) Applicant: Hewlett-Packard Development Company, L.P., Spring, TX (US)

(72) Inventors: Matthew D. Gaubatz, Seattle, WA (US); Robert Ulichney, Stow, MA (US)

(73) Assignee: Hewlett-Packard Development Company, L.P., Spring, TX (US)

(21) Appl. No.: 16/970,687

(22) PCT Filed: Apr. 23, 2018
(86) PCT No.: PCT/US2018/028846

§ 371 Date: Aug. 18, 2020

(51) Int. Cl. G06K 19/06; H03M 7/20; H03M 5/14

(52) U.S. Cl. CPC G06K 19/06037; H03M 5/145; H03M 7/20

(57) ABSTRACT

In example implementations, an apparatus is provided. The apparatus comprises a processor and a non-transitory computer readable storage medium encoded with instructions executable by a processor, the non-transitory computer-readable storage medium. The non-transitory computer readable storage medium includes instructions to receive a plurality of data having N bits, wherein each of the N bits is binary, select a set of code words for each one of the plurality of data, wherein the code words have M bits, wherein each of the M bits is binary having an approximately equal number of ones and zeros, wherein a value of M is greater than N, and print a reflection and inversion invariant code based on the set of code words to represent data of the plurality of data.

### BACKGROUND

Codes provide a short hand notation for providing information. Codes can be used to allow machines to read information. One example of such codes may be a bar code. A bar code may have a series of different lines with different thicknesses and spacing. The lines can be arranged to represent certain information.

Bar codes can be used to label a variety of different products. For example, bar codes are used to label products for sale, tickets, identification information on items, and the like.

### BRIEF DESCRIPTION OF THE DRAWINGS

FIG. 1 is a block diagram of a system to generate a reflection and inversion invariant code of the present disclosure;

FIG. 2 are example code books and example graphical representations of a code word in the code books of the present disclosure;

FIG. 3 is a flow chart of an example method for generating and printing a reflection and inversion invariant code of the present disclosure;

FIG. 4 is a flow chart of an example method for decoding a reflection and inversion invariant code that is scanned of the present disclosure; and

FIG. 5 is a block diagram of an example apparatus having a non-transitory computer readable storage medium storing instructions executed by a processor of the present disclosure.

### DETAILED DESCRIPTION

Examples described herein provide printed codes that are reflection and inversion invariant. As discussed above, bar codes can be used to allow machines to read information from the bar codes and label a variety of different products. However, bar codes are typically one-dimensional. In addition, bar codes may have a certain orientation or direction. As a result, reading a bar code in two different directions can result in different information being interpreted from the bar code.

Examples herein provide reflection and inversion invariant codes that can be printed onto any type of surface. The codes may be reflection invariant (e.g., can be read left to right or right to left). The codes may also be inversion invariant (e.g., can be read if the ones and zeros in the codes are swapped). In some cases, ones and zeros in the code may be swapped if the code is read upside down. Thus, the codes can be read in any direction or any orientation without changing the information that is obtained from the deciphering of the codes.

In one example, the codes can be generated by creating a representation of 1's and 0's. The codes may include an approximately equal number of 1′s and 0's. The codes can be abbreviated with canonical code words to save memory space and processing resources.

In one example, the codes may be applied in any number of dimensions. For example, the codes may be one dimensional, two-dimensional, or three-dimensional. Thus, the codes may be printed on a variety of different surfaces and be used in a variety of different applications.

FIG. 1 illustrates a system 100 that generates a reflection and inversion invariant code 110, prints the reflection and inversion invariant code 110, and scans and interprets the reflection and inversion invariant code 110. In one example, the system 100 includes a computing device 102, a reading device 104, and a printer 106.

In one example, the computing device 102 may be a desktop computer, a laptop computer, a tablet computer, a smart phone, and the like. The computing device 102 may include a processor and a computer readable memory that stores instructions executed by the processor to generate the reflection and inversion invariant code 110. The generation of the reflection and inversion invariant code 110 is discussed in further details below.

In one example, the computing device 102 may be communicatively coupled to a printer 106. The printer 106 may print the reflection and inversion invariant code 110. In one example, the reflection and inversion invariant code 110 may be printed on a print medium that is adhesive. The print medium with the reflection and inversion invariant code 110 may then be applied to an object 108. In one example, the printer 106 may be a hand held printer that may print the reflection and inversion invariant code 110 directly onto the object 108. In another example, the printer 106 may be a three-dimensional printer that may render the reflection and inversion invariant code 110 in the interior of a manufactured object 108.

The object 108 may be any type of product, device, material, and the like, that is to be labeled with the reflection and inversion invariant code 110. Information associated with the object 108 may be contained in the reflection and inversion invariant code 110.

In one example, the reading device 104 may scan, or read, the reflection and inversion invariant code 110 on the object 108. The reading device 104 may be a scanner, an optical code reader, and the like. The reading device 104 may include a processor and a computer readable memory that stores instructions executed by the processor to decode the reflection and inversion invariant code 110.

In one example, the reading device 104 may be communicatively coupled to the computing device 102. An image of the reflection and inversion invariant code 110 captured by the reading device 104 may be transmitted to the computing device 102. The computing device 102 may then decode the reflection and inversion invariant code 110.

In one example, the reflection and inversion invariant code 110 may be generated and printed such that the reflection and inversion invariant code 110 may be read with partial or inaccurate information about the symbols used (e.g., with the ones and zeros swapped, or even without explicit knowledge of the features distinguishing the ones from the zeros), in any orientation (e.g., upside down or right side up), and in any direction (e.g., left to right or right to left). As a result, the orientation or direction of the reflection and inversion invariant code 110, and the mapping between binary values and individual symbols of the reflection and inversion invariant code 110 may be irrelevant when being read by the reading device 104 and decoded by the reading device 104 or the computing device 102.

FIG. 2 illustrates example code books used to generate the reflection and inversion invariant code 110 of the present disclosure. A code book 202 illustrates an example table used to generate the reflection and inversion invariant code 110. The code book 202 may include data having N bits and equivalent code words for each data having M bits. In one example, the value of M may be arbitrarily chosen. In one example, the value of M may be a function of the value of N. In other words, the larger number of bits used in the data, the larger number of bits that may be used to generate the equivalent code words.

In one example, each bit of N bits of the data and each bit of the M bits of the equivalent code words may be a binary value. In other words, each bit may have a value of zero or a value of one.

The code book 202 represents a simple example where N equals 2 and M equals 4. However, it should be noted that N may be any value and the code book 202 for data where N is greater than 2 may be created similarly, as discussed below for the code book 202 where N equals 2.

In one example, the code book 202 may include all permutations of data having N bits. For example, for N=2, the data may include 00, 01, 10, and 11 as shown in the code book 202.

The equivalent code words may comprise at least one pair of code words having M bits for each value of the data in the code book 202. For example, for M=4 the equivalent code words to represent the data 00 may be 0011 and 1100, as shown in the code book 202. In one example, the equivalent code words may be selected arbitrarily from all possible combinations of M=4 binary bits that are reflection and inversion invariant.

In addition, the equivalent code words may have an equal weighting (e.g., equal number), or approximately equal weighting, of ones and zeros. In other words, when all of the combinations of equivalent code words with an equal weighting of ones and zeros are assigned to the data, equivalent code words with an approximately equal weighting of ones and zeros may be assigned to the data. For example, when M=4 an equal weighting of ones and zeros may have two ones and two zeros and an approximately equal weighting of ones and zeros may have three ones and one zero, or vice versa.

As can be seen in the code book 202, the equivalent code words may be a pair of equivalent code words that are reflections and/or inversions of each other. For example, 0011 read in an opposite direction may be 1100. Similarly, 0011 when read upside down, or with inverted values, may be read as 1100. Thus, when 0011 is read in any direction or orientation the values of 0011 or 1100 may be used to represent the data 00. The equivalent code words for the remaining data in the code book 202 may have similar properties.

In one example, the equivalent code words may be selected to have an equal weighting of ones and zeros or an approximately equal weighting of ones and zeros to allow a reading of the reflection and inversion invariant code 110 to be more efficiently decoded. With an approximately equal weighting of ones and zeros, the average position may be calculated and the deviation from the average position may be more easily detected.

In one example, the combinations of equivalent code words that are not used may be added to a row of invalid code words. For example, if an equivalent code word of 1111 was read, the code word may be determined to be an invalid code word based on the code book 202.

To illustrate, FIG. 2 illustrates a graphical representation 204 with a dot in a first position and a graphical representation 206 with a dot in a second position. The graphical representation 204 may have a value of zero and the graphical representation 206 may have a value of one.

In one example, the graphical representation 204 of the value of zero may be a dot in a lower side of a box. The graphical representation 206 of the value of one may be a dot in an upper side of the box. With an approximately equal weighting of ones and zeros, the decoder (e.g., the reading device 104 of the computing device 102) may calculate an average to be approximately the middle of the box and provide an accurate relative point to determine whether a dot is on a lower side or an upper side. As a result, the decoder may easily detect whether the dot is on the upper side of the average or on the lower side of the average to decipher the graphical representation 204 as a zero or the graphical representation 206 as a one.

In one example, a graphical representation 216 may represent a zero and a graphical representation 218 may represent a one. The graphical representations 216 and 218 may have geometric inversion invariance and/or luminance inversion invariance.

In another example, a graphical representation 220 may represent a zero and a graphical representation 222 may represent a one. It should be noted that the graphical representations 204 and 206, 216 and 218, and 220 and 222 are provided as examples and other graphical representations may be used or deployed.

A combination of the graphical representations 204 and 206 may be used to generate the reflection and inversion invariant code 110. For example, the data 00 may be printed as 0011 or 1100 using a combination of the graphical representations 204 and 206 as shown in the graphical representation 208. In one example, the reflection and inversion invariant code 110 may include a repeating string of the graphical representation 208.

In one example, when a repeating string of the graphical representation 208 is used, an image of at least M bits (e.g., 4 bits using the example above) may be captured to decode the reflection and inversion invariant code 110. In one example, a phase invariant property may be applied to the repeating string of the graphical representation 208 such that the reflection and inversion invariant code 110 can be read at any point of the repeating string.

In one example, the equivalent code words in the code book 202 may be replaced with canonical code words as shown in the code book 210. In one example, the canonical code word may be a short hand way of representing the pairs of equivalent code words for each value of data in the code book 202. The canonical code word may provide a more efficient way to generate a shorter graphical representation 208 and more efficient way to decode the reflection and inversion invariant code 110.

In one example, the canonical code word may add k additional bits to the M bit equivalent code words. In the example illustrated in the code book 210 k=1. Thus, the canonical code word may have a length of 5 bits (e.g., M=4 +k=1). However, it should be noted that k may have any value. For example, the value of k may be larger for data with a longer bit length.

In one example, the canonical code words may be selected from a list of all of the combinations of canonical code words having M+k length with a desired weighting. For example, the weighting may have an equal number of ones and zeros or an approximately equal number of ones and zeros. The list of canonical code words may be sorted, or organized, based on a maximum value or a minimum value. Then the canonical code words may be assigned to the equivalent code words for each data in the order selected (e.g., maximum value to minimum value or minimum value to maximum value). In one example, a scheme known as “Gosper's Hack” may be used to iterate through a set of constant weight code words to generate and select the canonical code words for the equivalent code words for each data in the code book 202.

In one example, the methods described above to generate the reflection and inversion invariant code 110 in one dimension may also be applied to generate a reflection and inversion invariant code 110 in two dimensions or three dimensions. For example, a two-dimensional data value 212 may be an X by Y array of binary bits where X=2 and Y=2, as illustrated in FIG. 2. The equivalent code words may be similarly created for the X by Y two-dimensional array as described above by applying the methods described above to each row and then each column. A two-dimensional array may be differently sized along each dimension, e.g., X and Y need not be identical.

Similarly, the canonical code word for each two-dimensional equivalent code word may be generated. For example, the canonical code word with k additional bits may be generated for each row of the two-dimensional equivalent code word and then for each column of the two-dimensional equivalent code word.

In three dimensions, a three-dimensional data value 214 may be an X by Y by Z array of binary bits where X=2, Y=2, and Z=2, as illustrated in FIG. 2. In other words, the three-dimensional data value 214 may be a plurality of two-dimensional arrays. The equivalent code words may be similarly created for the X by Y by Z three-dimensional array as described above by applying the methods described above to each row in the X direction, and then each column in the Y direction, and then to each row in the Z direction. A three-dimensional array may be of different sizes in each dimension, e.g., X, Y, and Z need not be identical and may be unique.

Similarly, the canonical code word for each three-dimensional equivalent code word may be generated. For example, the canonical code word with k additional bits may be generated for each row in the X direction of the three-dimensional equivalent code word, each column in the Y direction of the three-dimensional equivalent code word, and then each row in the Z direction of the three-dimensional equivalent code word.

In one example, the reflection and inversion invariant code 110 may be generated in two dimensions and three dimensions using the graphical representations 204 and 206. For example, a two-dimensional version of the reflection and inversion invariant code 110 may be a two-dimensional array of the graphical representations 204 and 206. A three-dimensional version of the reflection and inversion invariant code 110 may be a three-dimensional cube of the graphical representations 204 and 206.

Thus, the present disclosure may generate and print a reflection and inversion invariant code 110 that can be read in any direction and any orientation, if inverted, or even with partial or inaccurate information about which binary values are represented by which symbols. The reflection and inversion invariant code 110 may provide a more efficient code that can be easier to read and to decode. In addition, simple graphical representations 204 and 206 may be used to create the reflection and inversion invariant code 110. As a result, reflection and inversion invariant code 110 may be smaller and may fit on smaller areas of objects 108.

FIG. 3 illustrates a flow diagram of an example method 300 for generating and printing a reflection and inversion invariant code. In one example, the method 300 may be performed by a computing device 102 illustrated in FIG. 1, or the apparatus 500 illustrated in FIG. 5 and discussed below.

At block 302, the method 300 begins. At block 304, the method 300 generates a codebook, wherein the codebook comprises a table of different N bits of data and M bit code words for each one of the different N bits of data, wherein the M bit code words each comprise an approximately equal number of ones and zeros, wherein the N bits and the M bits are binary. For example, each N bit length of data may be represented by an M bit length code word. In one example, at least one pair of M bit length code words may be used to represent each N bit length of data. The M bit code words may be canonical representations of equivalent code words.

At block 306, the method 300 receives a selection of data from the table. For example, one of the N bit length data may be used to identify an object or to provide information associated with an object.

At block 308, the method 300 identifies an M bit code word from the table based on the selection of data. The table may determine which M bit length code words are associated with the N bit length data that is selected.

At block 310, the method 300 prints a reflection and inversion invariant code that represents the M bit code word. For example, graphical representations may be used to represent each bit of the M bit length code word. The reflection and inversion invariant code made be generated based on the series of the graphical representations, where each graphical representation in the series represents a value of one bit of the M bit length code word. The generated reflection and inversion invariant code may then be transmitted to a printer and the reflection and inversion invariant code may be printed.

In one example, the reflection and inversion invariant code may be printed onto an adhesive print medium that is applied to an object. In another example, the printer may be a portable hand held printer that can print directly onto objects. Thus, the reflection and inversion invariant code may be printed directly onto the object via the printer. At block 312, the method 300 ends.

FIG. 4 illustrates a flow diagram of an example method 400 for decoding a reflection and inversion invariant code that is scanned. In one example, the method 400 may be performed by the reading device 104 illustrated in FIG. 1.

At block 402, the method 400 begins. At block 404, the method 400 scans a reflection and inversion invariant code, wherein the reflection and inversion invariant code is decoded to provide identical information when read in any direction or orientation. As noted above, a reflection and inversion invariant code may be read in any direction or in any orientation. Thus, the reflection and inversion invariant code does not have to be moved, rotated, positioned, or aligned to be read.

In one example, the reflection and inversion invariant code that is scanned may be decoded locally by a reading device. In one example, an image of the reflection and inversion invariant code may be captured and transmitted to a computing device to perform the decoding of the reflection and inversion invariant code remotely.

At block 406, the method 400 decodes the reflection and inversion invariant code to a code word having an approximately equal number of ones and zeros. In one example, the reflection and inversion invariant code may be converted from graphical representations into a series of binary values (e.g., ones and zeros).

At block 408, the method 400 identifies a data associated with the code word. In one example, the series of binary values may be a canonical code word. A code book stored in memory may be used to translate the canonical code word directly to identify a data value.

In one example, the canonical code word may be translated into a non-canonical code word. For example, the canonical code word may be translated into an equivalent code word. Then the code book may be used to translate the equivalent code word and identify the data value.

In one example, the series of binary values may be an equivalent code word. The code book may be used to translate the equivalent code word to identify a data value. At block 410, the method 400 ends.

FIG. 5 illustrates an example of an apparatus 500. In one example, the apparatus 500 may include a processor 502 and a non-transitory computer readable storage medium 504. The non-transitory computer readable storage medium 504 may include instructions 506, 508, and 510 that, when executed by the processor 502, cause the processor 502 to perform various functions.

In one example, the instructions 506 may include instructions to receive a plurality of data having N bits, wherein each of the N bits is binary. The instructions 508 may include instructions to select a set of code words for each one of the plurality of data, wherein the code words have M bits, wherein each of the M bits is binary having an approximately equal number of ones and zeros, wherein a value of M is greater than N. The instructions 510 may include instructions to print a reflection and inversion invariant code based on the set of code words to represent data of the plurality of data.

It should be noted that the apparatus 500 has been simplified for ease of explanation and may include additional components not shown. For example, the apparatus 500 may include a display, an input device (e.g., a touch screen, a mouse, a keyboard, and the like), a communication interface to establish a wired or wireless communication path to external device (e.g., a printer to print the reflection and inversion invariant code), and the like.

It will be appreciated that variants of the above-disclosed and other features and functions, or alternatives thereof, may be combined into many other different systems or applications. Various presently unforeseen or unanticipated alternatives, modifications, variations, or improvements therein may be subsequently made by those skilled in the art which are also intended to be encompassed by the following claims.

1. An apparatus, comprising:
a processor; and
a non-transitory computer readable storage medium encoded with instructions executable by a processor, the non-transitory computer-readable storage medium comprising:
instructions to receive a plurality of data having N bits, wherein each of the N bits is binary;
instructions to select a set of code words for each one of the plurality of data, wherein the code words have M bits, wherein each of the M bits is binary having an approximately equal number of ones and zeros, wherein a value of M is greater than N; and
instructions to print a reflection and inversion invariant code based on the set of code words to represent data of the plurality of data.

2. The apparatus of claim 1, wherein the reflection and inversion invariant code comprises a graphical representation.

3. The apparatus of claim 1, wherein the set of code words comprises a code word that is a reflection of another code word.

4. The apparatus of claim 1, wherein the set of code words comprises a code words that is an inversion of another code word.

5. The apparatus of claim 1, wherein the set of code words are represented by a single canonical code word.

6. The apparatus of claim 1, wherein the reflection and inversion invariant code that is printed is a two-dimensional array.

7. The apparatus of claim 1, wherein the reflection and inversion invariant code that is printed comprises a plurality of two-dimensional arrays.

8. A method, comprising:
generating, by a processor, a codebook, wherein the codebook comprises a table of different N bits of data and M bit code words for each one of the different N bits of data, wherein the M bit code words each comprise an approximately equal number of ones and zeros, wherein the N bits and the M bits are binary;
receiving, by the processor, a selection of data from the table;
identifying, by the processor, an M bit code word from the table based on the selection of data; and
printing, by the processor, a reflection and inversion invariant code that represents the M bit code word.

9. The method of claim 8, wherein the reflection and inversion invariant code comprises a dot in a first position or in a second position.

10. The method of claim 8, wherein the M bit code words comprise a pair of reflected M bit code words.

11. The method of claim 8, wherein the M bit code words comprise a pair of inverted M bit code words.

12. The method of claim 8, wherein the reflection and inversion invariant code is printed in three dimensions on an object.

13. A method, comprising:
scanning, by a processor, a reflection and inversion invariant code, wherein the reflection and inversion invariant code is decoded to provide identical information when read in any direction or orientation;
decoding, by the processor, the reflection and inversion invariant code to code word having an approximately equal number of ones and zeros; and
identifying a data associated with the code word.

14. The method of claim 13, wherein the code word comprises a canonical code word.

15. The method of claim 14, further comprising:
translating, by the processor, the canonical code word into a non-canonical code word before the identifying.
